(19) United States
(12) Patent Application Publication
(10) Pub. No.: US 2005/0260799 A1
(43) Pub. Date: Nov. 24, 2005

(54) Semiconductor device and method for producing the same

(75) Inventor: Kaoru Ozawa, Minato-ku (JP)

Correspondence Address: SHINJYU GLOBAL IP COUNSELORS, LLP, 1233 20TH STREET, NW, SUITE 700, WASHINGTON, DC, 20036-2680, US

(73) Assignee: Oki Electric Industry Co., Ltd., Minato-ku (JP)

(21) Appl. No.: 10/980,239

(22) Filed: Nov. 4, 2004

(30) Foreign Application Priority Data
May 20, 2004 (JP) JP 2004-150283

(51) Int. Cl. H01L 21/00; H01L 27/01

(52) U.S. Cl. 438/149; 257/347

(57) ABSTRACT

The present invention provides a method for producing an SOI semiconductor device capable of forming a uniform field oxide film with good controllability. The method for producing a semiconductor device with an SOI substrate having a support substrate 1 and a semiconductor layer 3 that interpose a first insulating film 2 between them includes the following steps. A second insulating film 4 is overlaid on the semiconductor layer 3. A third insulating film 5 is overlaid on the second insulating film 4. An opening 9 is formed in the third and second insulating films 5 and 4, and the semiconductor layer 3 whereby the first insulating film 2 is exposed. A field oxide film 6 is formed by thermally oxidizing the support substrate 1 in the opening 9 through the first insulating film 2. The third and second insulating films 5 and 4 are removed.

### BACKGROUND OF THE INVENTION

1. Field of the Invention

The present invention generally relates to a semiconductor device. More specifically, the present invention relates to a semiconductor device and a method for producing a semiconductor device.

2. Background Information

In a conventional semiconductor device, various structures are devised as methods for separating respective transistors into elements. A typical technique is LOCOS (Local Oxidation of Silicon). In the LOCOS process, in a state in which a silicon nitride film (Si₃N₄) with oxidation resistance is partially formed on the surface of a silicon substrate, the substrate is thermally oxidized, and an element-separation portion is formed by locally oxidizing only the surface of the substrate where the silicon nitride film does not overlay.

Recently, in order to achieve high density and high performance in a semiconductor device, a semiconductor device is produced with an SOI (Silicon on Insulator) substrate in some cases. The LOCOS process is also widely used as an element-separation technique in the semiconductor device employing the SOI substrate similar to a semiconductor device employing a bulk substrate.

Semiconductor devices produced by an element-separation technique based on the LOCOS process are disclosed in Japanese Laid-Open Patent Publications TOKUKAI Nos. S58-122774 (especially pages 3-5, FIG. 2), H2-208953 (especially pages 2-3, FIG. 1), and H6-283522 (especially pages 3-5, FIGS. 1-4), the entire disclosures of which are hereby incorporated by reference.

An insulating substrate of sapphire is employed in the semiconductor device disclosed in JP S58-122774. Element Separation is performed with a first oxide film located on the insulating substrate. This first oxide film is formed by the LOCOS process. The first oxide film is formed by directly thermally oxidizing a silicon layer (SOI layer) formed on the insulating substrate.

With the semiconductor device disclosed in JP H2-208953, in an SOI substrate, an element-separation region is formed of a double structure composed of an oxide film formed by thermally oxidizing an SOI layer and a deposited oxide film formed by a CVD process. When this double structure is formed, the SOI layer in the element-separation region is removed except for a portion near the boundary of the insulating film. The SOI layer that remains near the boundary is thermally oxidized. Since a thermal oxide film based on the remaining SOI layer alone cannot provide sufficient film thickness, the deposited oxide film formed by a CVD (Chemical Vapor Deposition) process compensates for the shortage. The reason for the partial removal of the SOI layer is to ensure that the time required for the thermal oxidation process is short.

The semiconductor device disclosed in JP H6-283522 relates to an element-separation method that keeps in check the spread of an oxide film to the end of an element region, a so-called bird's beak, which causes a problem in the element-separation by the LOCOS process.

The bird's beak appears when the sidewalls of a silicon nitride film, which is an oxidation mask layer, are exposed under an oxidation atmosphere in a thermal oxidation process of an SOI layer. With this semiconductor device, another silicon nitride film additionally overlays the sidewalls of the silicon nitride film, which is the oxidation mask layer, and thus prevents oxygen from getting into the element region in the thermal oxidation process. Since the silicon nitride layers are doubly formed, a pad oxide film and a pad poly silicon film reduce the stress on a substrate.

As mentioned in JP S58-122774 and JP H2-208953, when elements are separated on the SOI substrate by the LOCOS process, the oxide film (field oxide film), which forms the element-separation region, is basically formed by thermally oxidizing the SOI layer. However, the SOI layer is typically thin with a thickness on the order of several tens nm. Additionally, when an opening is formed by removing the silicon nitride film in the element-separation region, the SOI layer directly under the opening becomes thinner by over etching. Accordingly, the thermal oxide film with a thickness required for element-separation cannot be formed.

In JP H6-283522, though the bird's beak is kept in check by the double structure of the silicon nitride films, formation of this structure requires double stress relaxation layers and causes complexity in terms of the processes used to produce the device.

In view of the above, it will be apparent to those skilled in the art from this disclosure that there exists a need for an improved a semiconductor device and a method for producing a semiconductor device. This invention addresses this need in the art as well as other needs, which will become apparent to those skilled in the art from this disclosure.

### SUMMARY OF THE INVENTION

A method for producing a semiconductor device in an SOI substrate having a support substrate and a semiconductor layer that interpose a first insulating film between the support substrate and semiconductor layer according to a first aspect of the present invention includes steps of overlaying a second insulating film on the semiconductor layer; overlaying a third insulating film on the second insulating film; forming an opening in the third and second insulating films, and the semiconductor layer exposing the first insulating film; forming a field oxide film by thermally oxidizing the support substrate in the opening through the first insulating film; and removing the third and second insulating films.

The method for producing a semiconductor device according to a second aspect of the present invention is the method of the first aspect and further includes a step of forming a fourth insulating film on the inner walls of the opening after the step of forming an opening.

The method for producing a semiconductor device according to a third aspect of the present invention is the method of the first or second aspect, wherein the semiconductor layer (SOI layer) in the element-separation region is removed, and the support substrate with a sufficient thickness is thermally oxidized, therefore, the field oxide film can be uniformly formed with good controllability.

The method for producing a semiconductor according to a fourth aspect of the present invention is the method of the second or third aspect, wherein the inner walls of the opening is protected by the insulating film (fourth insulating film) with the same thermal expansion coefficient as the insulating layer (first insulating film) of the SOI substrate. In other words, the sidewalls of the semiconductor layer are not exposed in the opening, therefore, the spread of bird's beak to the end of an element region can be kept in check, and the stress on the semiconductor layer can be reduced.

These and other objects, features, aspects, and advantages of the present invention will become apparent to those skilled in the art from the following detailed description, which, taken in conjunction with the annexed drawings, discloses a preferred embodiment of the present invention.

### BRIEF DESCRIPTION OF THE DRAWINGS

Referring now to the attached drawings which form a part of this original disclosure:

FIG. 1 is a cross-sectional view of a method for producing an SOI semiconductor device according to a first preferred embodiment of the present invention; and

FIG. 2 is a cross-sectional view of a method for producing an SOI semiconductor device according to a second preferred embodiment of the present invention.

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

### First Embodiment

In a first embodiment, a field oxide film is formed by thermally oxidizing a support substrate of an SOI substrate.

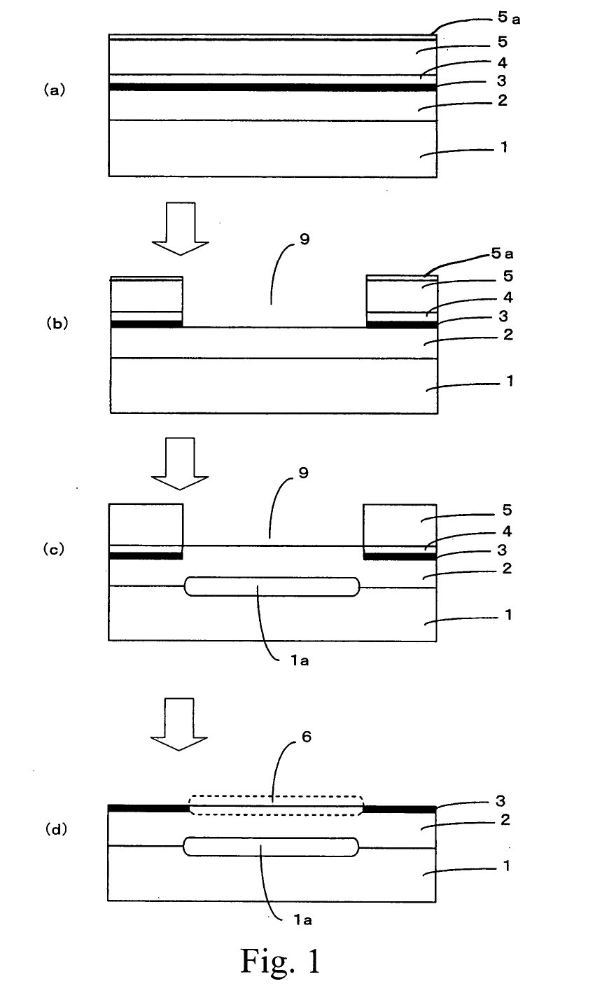

FIG. 1 shows cross-sectional views illustrating a method for producing an SOI semiconductor device according to a first preferred embodiment of the present invention. This SOI semiconductor device preferably operates in a fully depleted (FD) mode. The SOI semiconductor device, however, may be a partially depleted (PD) SOI semiconductor device. The present invention is effective particularly for an SOI semiconductor device having an SOI layer formed to be thin with a thickness that does not exceed 50 nm, for example. However, the effect does not depend on the thickness of the SOI layer, and the present invention can be applied to general semiconductor devices which have an SOI substrate.

As shown in line (a) of FIG. 1, an SOI substrate which includes a support substrate I of silicon, a buried oxide film (BOX) 2 (first insulating film), and a semiconductor layer (SOI layer) 3 of single crystal silicon is prepared. The SOI substrate can be a SIMOX (Silicon Implanted Oxide) substrate or a bonded substrate.

Then, a silicon oxide film 4 is formed on the semiconductor layer 3 by thermal oxidation, and a silicon nitride film (Si₃N₄) 5 is deposited by a CVD process. This silicon nitride film 5 serves as an oxidation-reduction mask when a field oxide film 6 described later is formed. Thus, the silicon oxide film 4 forms a second insulating film, and the silicon nitride film 5 forms a third insulating film.

Next, a photoresist film 5a is applied on the silicone nitride film 5. A resist pattern with an opening corresponding to a region above the element-separation region is formed on the silicon nitride film 5 through exposure and development processes. The silicon nitride film 5, the silicon oxide film 4, and the semiconductor layer 3 are selectively and successively etched with the resist pattern as a mask by reactive ion etching (RIE). Thus, as shown in line (b) of FIG. 1, an opening 9, which exposes the buried oxide film 2 in the element-separation region, is formed. At this time, the semiconductor layer 3 is completely removed inside the opening 9. Of course, it follows that the area around the opening 9 is an element-forming portion.

After the photoresist film 5a is removed, the support substrate I in the element-separation region is thermally oxidized through the buried oxide film 2 by a dry or wet process. Accordingly, as shown in line (c) of FIG. 1, the support substrate 1 on the buried oxide film 2 side under the opening 9 is thermally oxidized, and expands so that a silicon oxide film la is formed, thus the buried oxide film 2 is thrust upwardly. As a result, the surface of the buried oxide film 2, more precisely, the exposed surface thereof, rises to a height similar to the surface of the silicon oxide film 4 that contacts the silicon nitride film 5.

Subsequently, the silicon nitride film 5 is removed, then the silicon oxide film 4 and the exposed surface of the buried oxide film 2 are removed so that the semiconductor layer 3 is exposed. Consequently, the field oxide film 6 made of the buried oxide film 2 is formed as shown in line (d) of Fig I.

Operation/Working-Effect

According to the method for producing the SOI semiconductor device of the first embodiment, the support substrate I of silicon with a sufficient thickness is thermally oxidized when the field oxide film 6 is formed. Therefore, the field oxide film 6 with a sufficient thickness can be uniformly formed with good controllability when compared to the case in which the semiconductor 3 with a small thickness is thermally oxidized.

As used herein, the following directional terms “forward, rearward, above, downward, vertical, horizontal, below, and transverse” as well as any other similar directional terms refer to those directions of a device equipped with the present invention. Accordingly, these terms, as utilized to describe the present invention should be interpreted relative to a device equipped with the present invention.

### SECOND EMBODIMENT

A second embodiment will now be explained. In view of the similarity between the first and second embodiments, the parts of the second embodiment that are identical to the parts of the first embodiment will be given the same reference numerals as the parts of the first embodiment. Moreover, the descriptions of the parts of the second embodiment that are identical to the parts of the first embodiment may be omitted for the sake of brevity.

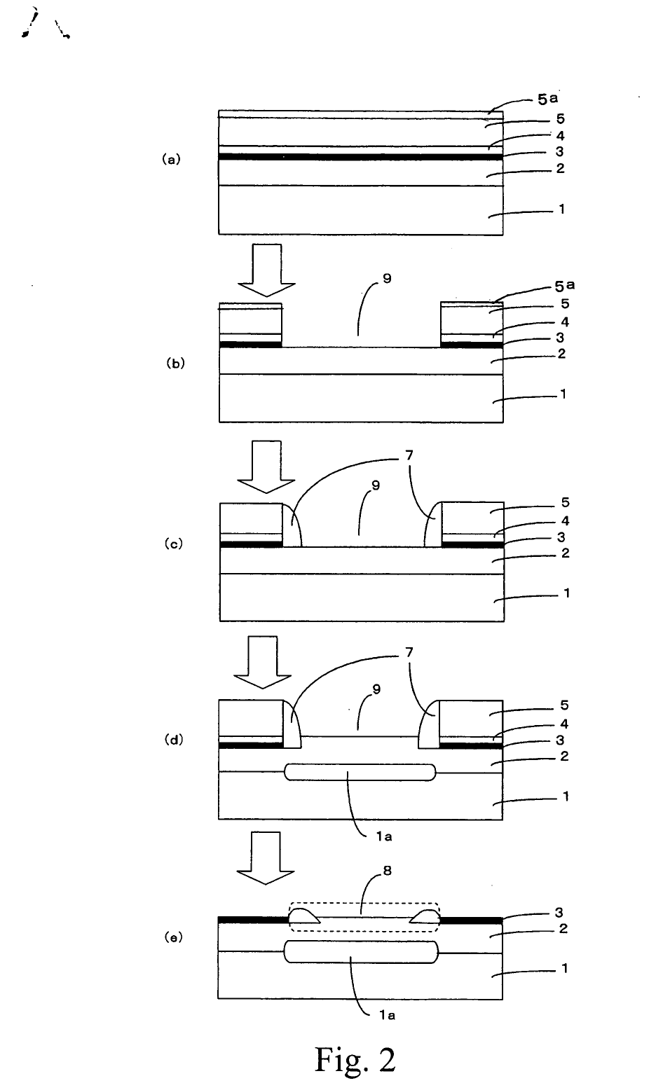

In a second preferred embodiment of the present invention, an insulating film 7 (see FIG. 2) is also formed on the inner walls of the opening 9 prior to thermal oxidation on the support substrate 1.

FIG. 2 shows cross-sectional views illustrating a method for producing an SOI semiconductor device according to a second preferred embodiment of the present invention.

An SOI substrate similar to that of the first embodiment is prepared as shown in line (a) of FIG. 2.

Next, as shown in line (b) of FIG. 2, the opening 9 is formed by completely removing the semiconductor layer 3 in the element-separation region similar to the first embodiment, and the buried oxide film 2 is exposed inside the opening 9.

Then, a silicon oxide film 7 is deposited on the silicon nitride film 5 and inside the opening 9 by a CVD process. A material with the same thermal expansion coefficient as the buried oxide film 2 is selected as this silicon oxide film 7. The silicon oxide film 7 may be formed by an application such as an SOG (Spin on Glass) process. An etch back process is performed on the silicon oxide film 7 by anisotropic etching such as reactive ion etching. Thus, the silicon oxide film 7 is formed as a protection film only on the inner walls of the opening 9 as shown in line (c) of FIG. 2. This silicon oxide film 7 is formed in order for the sidewalls of the semiconductor layer 3 not to be exposed inside the opening 9 in subsequent thermal oxidation. More specifically, the silicon oxide film 7 covers the sidewalls of the semiconductor layer 3.

Subsequently, similar to the first embodiment, the support substrate I in the element-separation region is thermally oxidized through the buried oxide film 2, thus, the silicon oxide film la is formed. This thermal oxidation of the support substrate I raises the buried oxide film 2 as shown in line (d) of FIG. 2.

After the thermal oxidation of the support substrate 1, the silicon nitride film 5 is removed, and the silicon oxide film 4 and exposed surface of the buried oxide film 2 are removed so that the semiconductor layer 3 is exposed. At that time, the silicon oxide film 7 is also partially etched. Through the above processes, a field oxide film 8 composed of the buried oxide film 2 and the silicone oxide film 7 is formed as shown in line (e) of FIG. 2.

In the case that the silicon oxide film 4 and the buried oxide film 2 are etched by a chemical solution with an etching rate for a CVD oxide film higher than for a thermal oxide film when removed, a protruding shape of the silicon oxide film 7 formed by a CVD process can be small, therefore, it is possible to improve flatness. For example, in the case that the silicon oxide film 7 is formed by an LP-CVD (Low Pressure Chemical Vapor Deposition) process, when hydrofluoric acid (HF) is employed as an etching solution, the etching rate for the silicon oxide film 7 is 5 to 7 times the rate for the silicon oxide film 4.

Operation/Working-Effect

According to the method for producing the SOI semiconductor device of the second embodiment, the sidewalls of the semiconductor layer 3 are protected by the silicone oxide film 7 when the support substrate 1 is thermally oxidized, therefore, it is possible to keep the spread of bird's beak to the inside of the semiconductor layer 3 in check.

Moreover, since the thermal expansion coefficients of the silicon oxide film 7 and the buried oxide film 2 are same, it is possible to reduce or to relax the stress on the semiconductor layer 3.

The term “configured” as used herein to describe a component, section or part of a device includes hardware and/or software that is constructed and/or programmed to carry out the desired function.

Moreover, terms that are expressed as “means-plus function” in the claims should include any structure that can be utilized to carry out the function of that part of the present invention.

The terms of degree such as “substantially,” “about,” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

This application claims priority to Japanese Patent Application No. 2004-150283. The entire disclosure of Japanese Patent Application No. 2004-150283 is hereby incorporated herein by reference.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

1. A method for producing a semiconductor device comprising:
preparing an SOI substrate having a first insulating film between a support substrate and a semiconductor layer;
overlaying a second insulating film on said semiconductor layer;
overlaying a third insulating film on said second insulating film;
forming an opening in said third and second insulating films, and said semiconductor layer to expose said first insulating film;
forming a field oxide film by thermally oxidizing said support substrate in said opening through said first insulating film; and
removing said third and second insulating films.

2. The method for producing a semiconductor device according to claim 1, wherein said semiconductor layer is completely removed in said opening.

3. The method for producing a semiconductor device according to claim 1, further comprising forming a fourth insulating film on inner walls of said opening after forming said opening.

4. The method for producing a semiconductor device according to claim 3, wherein said fourth insulating film is a silicon oxide film formed by a CVD process or an SOG process.

5. The method for producing a semiconductor device according to claim 1, wherein said first and second insulating films are silicon oxide films, and said third insulating film is a silicon nitride film.

6. A semiconductor device comprising:
a support substrate having a protruding portion and a flat portion;
a first insulating film being formed on said flat portion;
a second insulating film being formed integrally with said first insulating film on said protruding portion; and
a semiconductor layer being formed on said first insulating film adjacent to said second insulating film.

7. The semiconductor device according to claim 6, wherein said protruding portion is a thermal oxide film.

8. The semiconductor device according to claim 6, further comprising a third insulating film arranged between said second insulating film and said semiconductor layer.

9. The semiconductor device according to claim 8, wherein said third insulating film is a silicon oxide film formed by a CVD process or an SOG process.

10. The semiconductor device according to claim 6, wherein said first and second insulating films are silicon oxide films.

11. A semiconductor device comprising:
an element-forming portion including a first support substrate, a first insulating film being formed on said first support substrate, and a semiconductor layer being formed on said first insulating layer; and
an element-separation portion including a second support substrate having a thickness larger than that of said first support substrate on said first insulating film side formed adjacent to and integrally with said first support substrate, and a second insulating film being arranged adjacent to said semiconductor layer, formed integrally with said first insulating film on said second insulating substrate adjacent to said semiconductor layer.

12. The semiconductor device according to claim 11, wherein said second support substrate has a thermal oxide film on said second insulating film side.

13. The semiconductor device according to claim 11, further comprising a third insulating film arranged between said semiconductor layer and said second insulating film.

14. The semiconductor device according to claim 13, wherein said third insulating film is a silicon oxide film formed by a CVD process or an SOG process.

15. The semiconductor device according to claim 11, wherein said first and second insulating films are silicon oxide films.
